(19) United States
(12) Patent Application Publication
(10) Pub. No.: US 2021/0208182 A1
(43) Pub. Date: Jul. 8, 2021

(54) PROBE CARD, PROBING SYSTEM AND PROBING METHOD

(71) Applicant: TECAT TECHNOLOGIES (SUZHOU) LIMITED, SUZHOU (CN)

(72) Inventor: CHOON LEONG LOU, SINGAPORE (SG)

(21) Appl. No.: 16/783,729

(22) Filed: Feb. 6, 2020

(30) Foreign Application Priority Data
Jan. 3, 2020 (CN) 202010004449.0

(51) Int. Cl. G01R 1/07; G01R 1/073

(52) U.S. Cl. CPC G01R 1/071; G01R 1/07342

(57) ABSTRACT

A probe card includes a frame; a supporting member disposed on and protruding from the frame; an opening extending through the frame and into the supporting member; an optical fiber disposed along and protruding from the supporting member; and a plurality of probes protruding from the frame and disposed adjacent to the optical fiber.

### TECHNICAL FIELD

The present disclosure relates to a probe card integrated with at least one optical fiber, and particularly relates to a membrane probe card integrated with a fiber array block (FAB). Further, the present disclosure relates to a probing system including a probe card integrated with at least one optical fiber, disposed above a chuck and mounted on a circuit board. Further, the present disclosure relates to a probing method for testing a device under test (DUT) by a probe card integrated with at least one optical fiber.

### DISCUSSION OF THE BACKGROUND

After fabrication, a semiconductor device under test (DUT), such as a wafer that includes dies, is tested by a probing system. A probe card is is used to test electrical properties of the DUT in order to select and discard any defective DUTs. The probe card generally includes several probes protruding from the probe card, wherein the position of each probe is aligned with the corresponding contact pad over the DUT in order to accurately and consistently carry out electrical testing.

However, the miniature scale of current DUTs makes for increasingly complicated testing of the small and thin DUT, including many steps and operations that are difficult to perform at such a scale. Further, to reduce cost, the probe card is generally equipped with increasing numbers of probes to contact multiple contact pads of the DUT, so that testing can be performed on several dies at the same time. An increase in a complexity of testing may decrease an accuracy of the testing.

As such, there is a continuous need to improve a configuration of the probe card and the probing method.

This Discussion of the Background section is provided for background information only. The statements in this Discussion of the Background are not an admission that the subject matter disclosed in this Discussion of the Background section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a probe card. The probe card includes a frame; a supporting member disposed on and protruding from the frame; an opening extending through the frame and into the supporting member; an optical fiber disposed along and protruding from the supporting member; and a plurality of probes protruding from the frame and disposed adjacent to the optical fiber.

In some embodiments, the optical fiber is surrounded by the plurality of probes.

In some embodiments, the plurality of probes are protruded from a dielectric membrane disposed on the frame and along the supporting member, and the optical fiber is surrounded by the dielectric membrane.

In some embodiments, the optical fiber is disposed within the opening or along a surface of the supporting member.

In some embodiments, the optical fiber is at least partially attached to the supporting member.

In some embodiments, the optical fiber is a fiber array block (FAB) or includes a plurality of optical fibers.

In some embodiments, the supporting member is made of glass or ceramic.

In some embodiments, the dielectric membrane is at least partially is attached to the supporting member.

In some embodiments, the supporting member is spaced apart from the plurality of probes.

In some embodiments, the dielectric membrane is flexible.

In some embodiments, the plurality of probes are electrically connected to a circuit board through a plurality of signal traces.

Another aspect of the present disclosure provides a probing system. The probing system includes a circuit board; a probe card including a frame mounted on the circuit board, a supporting member protruding from the frame, an opening extending through the frame and the supporting member, an optical fiber disposed along and protruding from the supporting member, and a plurality of probes protruding from the frame and disposed adjacent to the optical fiber; and a chuck configured to support a device under test (DUT), wherein the supporting member and the optical fiber are disposed above the chuck.

In some embodiments, the supporting member and the optical fiber are surrounded by and protrude from the circuit board.

In some embodiments, an end of the optical fiber is aligned with a corresponding coupler over the DUT.

In some embodiments, the probing system further includes a stage disposed within the opening and configured to displace and orient the supporting member and the optical fiber.

In some embodiments, the supporting member is displaceable relative to the circuit board.

Another aspect of the present disclosure provides a probing method. The method includes providing a circuit board, a probe card over the circuit board, a chuck under the circuit board and the probe card, and a device under test (DUT) on the chuck, wherein the probe card includes a frame mounted on the circuit board, a supporting member protruding from the frame, an opening extending through the frame and the supporting member, an optical fiber disposed along and protruding from the supporting member, and a plurality of probes protruding from the frame and disposed adjacent to the optical fiber; aligning an end of the optical fiber with a coupler over the DUT; and probing a plurality of pads over the DUT by the plurality of probes.

In some embodiments, the alignment includes moving or rotating the supporting member relative to the DUT.

In some embodiments, the DUT is probed by the plurality of probes by moving the supporting member toward the DUT, or moving the chuck and the DUT toward the probe card.

In some embodiments, the method further includes: transmitting an optical signal to the DUT through the optical fiber; and transmitting a response signal from the DUT to the plurality of probes in response to the optical signal.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures.

FIG. 1 is a schematic cross-sectional view of a membrane type probe card in accordance with some embodiments of the present disclosure.

FIG. 2 is a schematic cross-sectional view of a cantilever type probe card in accordance with some embodiments of the present disclosure.

FIG. 3 is a schematic cross-sectional view of a vertical type probe card in accordance with some embodiments of the present disclosure.

FIG. 4 is a schematic cross-sectional view of a probing system in accordance with some embodiments of the present disclosure.

FIG. 5 is a flowchart representing a probing method in accordance with some embodiments of the present disclosure.

FIGS. 6 to 8 are schematic views of the probing method of FIG. 5 in accordance with some embodiments of the present disclosure.

### DETAILED DESCRIPTION

The following description of the disclosure accompanies drawings, which are incorporated in and constitute a part of this specification, and illustrate embodiments of the disclosure, but the disclosure is not limited to the embodiments. In addition, the following embodiments can be properly integrated to complete another embodiment.

References to “one embodiment,” “an embodiment,” “exemplary embodiment,” “other embodiments,” “another embodiment,” etc. indicate that the embodiment(s) of the disclosure so described may include a particular feature, structure, or characteristic, but not every embodiment necessarily includes the particular feature, structure, or characteristic. Further, repeated use of the phrase “in the embodiment” does not necessarily refer to the same embodiment, although it may.

In order to make the present disclosure completely is comprehensible, detailed steps and structures are provided in the following description. Obviously, implementation of the present disclosure does not limit special details known by persons skilled in the art. In addition, known structures and steps are not described in detail, so as not to unnecessarily limit the present disclosure. Preferred embodiments of the present disclosure will be described below in detail. However, in addition to the detailed description, the present disclosure may also be widely implemented in other embodiments. The scope of the present disclosure is not limited to the detailed description, and is defined by the claims.

In the present disclosure, a probe card is disclosed. The probe card includes an optical fiber supported by a supporting member, and several probes surrounding the optical fiber. The probe card is integrated with the optical fiber and the probes. As such, the probe card is suitable for silicon photonics probing. Transmission of both electrical and optical signals through the probe card is allowed, and signal transmission speed can be increased or improved. As a result, an efficiency of the testing of the DUT can be increased.

Furthermore, the probe card can integrate with several optical fibers or a fiber array block (FAB) including a bundle of optical fibers. Prior to probing or testing of the DUT, the probe card must be aligned with the DUT. In other words, each of the optical fibers is aligned with the corresponding component (e.g., coupler, pad, etc.) over the DUT. As such, the alignment of the probe card can result in alignment of all of the optical fibers at the same is time. Therefore, time and effort spent on the alignment can be reduced.

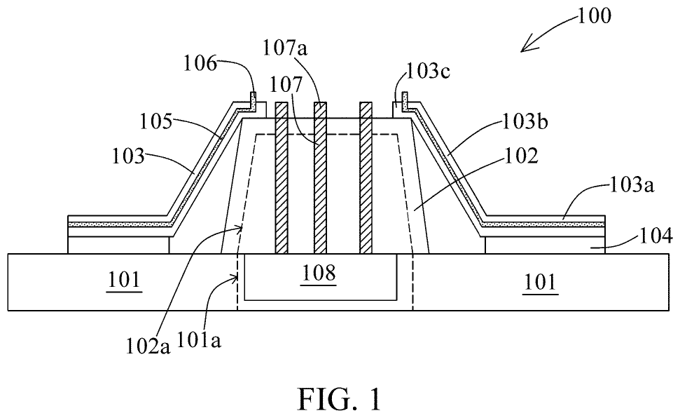

FIG. 1 is a schematic cross-sectional view of a first probe card 100 in accordance with various embodiments of the present disclosure. In some embodiments, the first probe card 100 is configured to perform testing of a wafer, a device under test (DUT), a die, an integrated circuit (IC) or the like. In some embodiments, the first probe card 100 is configured to perform electrical, optical or radio frequency (RF) testing. In some embodiments, the first probe card 100 is configured to be mounted on a printed circuit board (PCB), a platen or the like. The first probe card 100 is integrated with at least one optical fiber 107. As such, the first probe card 100 allows high-speed signal transmission and efficient silicon photonics probing. In some embodiments, the first probe card 100 is a membrane type probe card.

In some embodiments, the first probe card 100 includes a frame 101. In some embodiments, the frame 101 has a rectangular, quadrilateral or polygonal shape. In some embodiments, the frame 101 is made of metal, alloy, ceramic, conductive material, non-conductive material or the like. In some embodiments, the frame 101 is a rigid structure.

In some embodiments, the frame 101 includes a first opening 101a at a central portion of the frame 101. In some embodiments, the first opening 101a extends through the frame 101. In some embodiments, the first opening 101a has a rectangular, quadrilateral or polygonal shape.

In some embodiments, the first probe card 100 includes a supporting member 102 disposed on the frame 101. In some embodiments, the supporting member 102 protrudes from the frame 101. In some embodiments, is the supporting member 102 is attached to an edge of the first opening 101a of the frame 101. In some embodiments, the supporting member 102 is tapered from the frame 101. In some embodiments, the supporting member 102 is made of glass, ceramic, plastic or the like.

In some embodiments, the supporting member 102 includes a second opening 102a extending from the frame 101. In some embodiments, the second opening 102a is aligned with the first opening 101a of the frame 101, such that there is an opening extending through the frame 101 and into the supporting member 102.

In some embodiments, a dielectric membrane 103 is disposed on the frame 101 and the supporting member 102. In some embodiments, the dielectric membrane 103 is attached to the frame 101 and disposed along the supporting member 102. In some embodiments, the dielectric membrane 103 is spaced apart from the supporting member 102. In some embodiments, the dielectric membrane 103 is flexible and bendable. In some embodiments, the dielectric membrane 103 includes dielectric, polymeric or insulative material. In some embodiments, the dielectric membrane 103 is transparent or semi-transparent.

In some embodiments, the dielectric membrane 103 is at least partially attached to the frame 101 and the supporting member 102. In some embodiments, a horizontal portion 103a of the dielectric membrane 103 is disposed on and attached to the frame 101, an inclined portion 103b of the dielectric membrane 103 is disposed along an outer surface of the supporting member 102, and an end portion 103c of the dielectric membrane 103 is attached to the supporting member 102. In some embodiments, the horizontal portion 103a is attached to the frame 101 by a buffer layer 104. In some embodiments, the buffer layer 104 includes soft or deformable material.

In some embodiments, several signal traces 105 are disposed within the dielectric membrane 103. In some embodiments, the signal trace 105 extends along the dielectric membrane 103. In some embodiments, the signal trace 105 is configured to connect with a contact pad or a circuitry external to the first probe card 100. In some embodiments, the signal trace 105 is electrically conductive. In some embodiments, the signal trace 105 includes metallic material such as copper, gold or the like.

In some embodiments, several probes 106 protrude from the dielectric membrane 103. In some embodiments, the probe 106 is electrically coupled to the signal trace 105, such that the probe 106 is electrically connected to a contact pad or circuitry external to the first probe card 100 through the signal trace 105. In some embodiments, a signal (e.g., electrical, RF or optical signal) can be transmitted from an external circuitry or manipulator to the probe 106 through the signal trace 105. In some embodiments, the probe 106 is configured to transmit or receive a signal.

In some embodiments, the optical fiber 107 is disposed along the supporting member 102. In some embodiments, the optical fiber 107 is configured to transmit or receive an optical signal. In some embodiments, the optical fiber 107 is disposed on the surface of the supporting member 102. In some embodiments, the optical fiber 107 is elongated from the frame 101 and along the supporting member 102. In some embodiments, the optical fiber 107 is at least partially attached to the supporting member 102. In some embodiments, the optical fiber 107 is at least partially spaced apart from the supporting member 102. In some embodiments, the optical fiber 107 is surrounded by the probe 106. In some embodiments, the optical fiber 107 is surrounded by the dielectric membrane 103. In some embodiments, the optical fiber 107 is disposed within the second opening 102a of the supporting member 102.

In some embodiments, an end portion 107a of the optical fiber 107 protrudes from the supporting member 102. In some embodiments, the end portion 107a of the optical fiber 107 is configured to couple to a component (e.g., coupler or the like) over the DUT. In some embodiments, a fiber array block (FAB) including several optical fibers 107 is disposed on the supporting member 102.

In some embodiments, a stage 108 is disposed within the opening (101a and 102a) and configured to displace and orient the supporting member 102 and the optical fiber 107. In some embodiments, the supporting member 102 is movable along its two axes (X and Y axes). In some embodiments, the supporting member 102 is movable along its three axes (X, Y and Z axes). In some embodiments, the supporting member 102 is rotatable about one or more of its three axes (X, Y and Z axes). In some embodiments, the movement or the rotation of the supporting member 102 can be operated manually or motorized (e.g. by one or more motor).

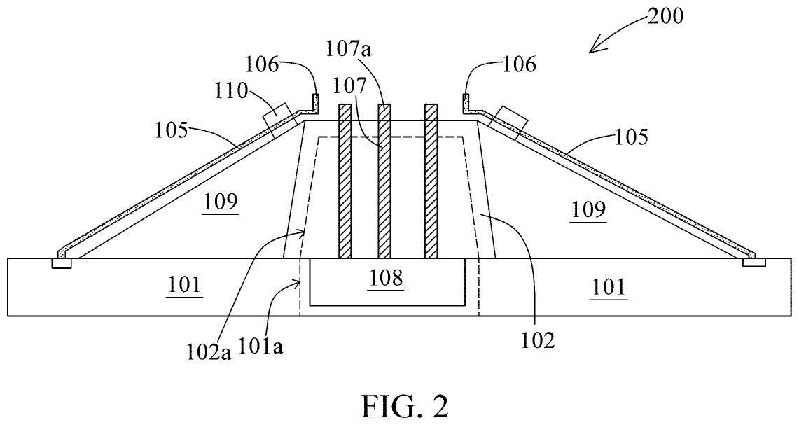

FIG. 2 is a schematic cross-sectional view of a second probe card 200 in accordance with various embodiments of the present disclosure. In some embodiments, the second probe card 200 is similar to the first probe card 100, except the probes 106 of the second probe card 200 are held by a holder 109 and a fastening means 110. In some embodiments, the second probe card 200 is a cantilever type probe card. In some embodiments, the probes 106 are disposed adjacent to the optical fiber 107. In some embodiments, the probes 106 surround the optical fiber 107 and the supporting member 102. In some embodiments, the second probe card 200 is a MEMS probe card, that the probes 106 are MEMS probes.

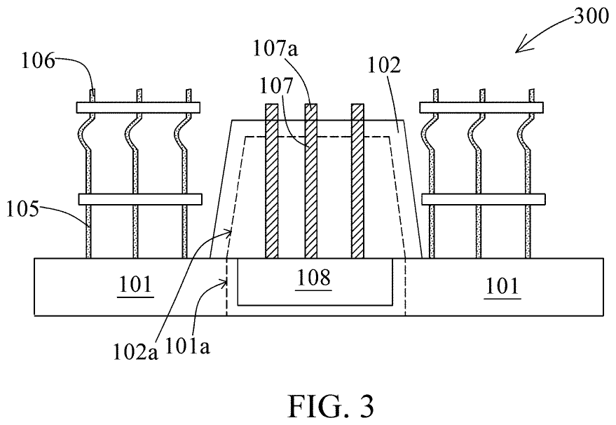

FIG. 3 is a schematic cross-sectional view of a third probe card 300 in accordance with various embodiments of the present disclosure. In some embodiments, the third probe card 300 is similar to the first probe card 100 and the second probe card 200, except the probes 106 of the third probe card 300 are vertical probes vertically protruded from the third probe card 300. In some embodiments, the third probe card 300 is a vertical type probe card.

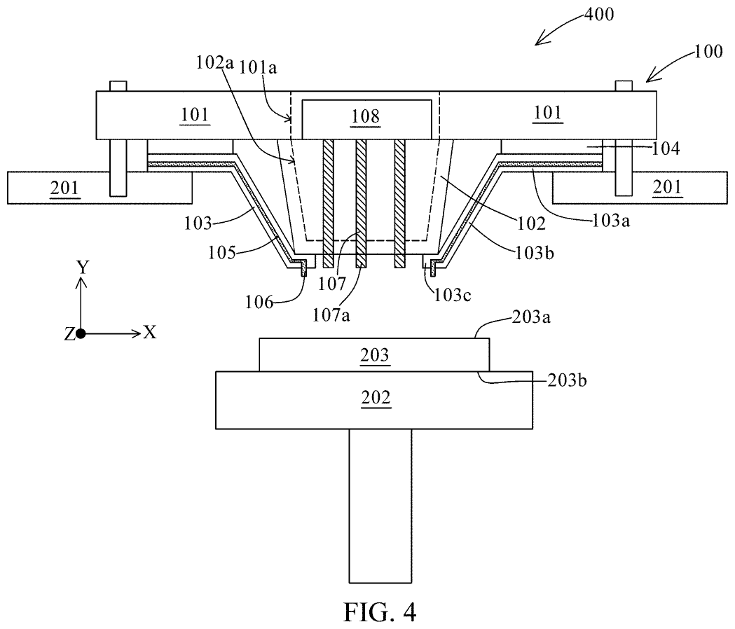

FIG. 4 is a schematic cross-sectional view of a probing system 400 in accordance with various embodiments of the present disclosure. In some embodiments, the probing system 400 includes the first probe card 100, a circuit board 201 and a chuck 202. FIG. 4 only illustrates use of the first probe card 100 in the probing system 400, however it is not intended to be limited to such embodiment. A person ordinarily skilled in the art would readily understand that the second probe card 200, the third probe card 300 or any other suitable types of probe cards can also be utilized in the probing system 400, and all such embodiments are fully intended to be included within the scope of the present disclosure.

In some embodiments, the circuit board 201 is configured to hold and support the first probe card 100. In some embodiments, the first probe card 100 in FIG. 1 is flipped over and mounted on the circuit board 201. In some embodiments, the first probe card 100 is mounted on the circuit board 201 by a screw, a clamp or any other suitable fastening means. FIG. 4 only illustrates the first probe card 100 is mounted on the circuit board 201, however it is not intended to be limited to such embodiment. A person ordinarily skilled in the art would readily understand that the second probe card 200, the third probe card 300 or any other suitable types of probe cards can also be mounted on the circuit board 201, and all such embodiments are fully intended to be included within the scope of the present disclosure.

In some embodiments, the circuit board 201 includes a circuitry disposed over or within the circuit board 201 and configured to connect the signal trace 105 to a tester or probe head external to the probing system 400. In some embodiments, the probe 106 is electrically connected to the tester or probe head through the circuit board 201 and the signal trace 105. In some embodiments, the circuit board 201 is a flexible printed circuit board or the like.

In some embodiments, a connector is disposed over the circuit board 201 and is configured to contact an end portion of the signal trace 105. In some embodiments, the connector is disposed between the circuit board 201 and the dielectric membrane 103. In some embodiments, the supporting member 102, the optical fiber 107 and the dielectric membrane 103 of the first probe card 100 are surrounded by and protrude from the circuit board 201.

In some embodiments, the chuck 202 is configured to hold and support the DUT 203. In some embodiments, the chuck 202 is rotatable about a center of the chuck 202 and is movable toward and away from the first probe card 100. In some embodiments, the chuck 202 has a circular, quadrilateral or polygonal shape. In some embodiments, the supporting member 102 and the optical fiber 107 are disposed above the chuck 202.

In some embodiments, the DUT 203 is disposed on the chuck 202 during probing or testing operations. In some embodiments, the DUT 203 is held on the chuck 202 by sucking the DUT 203 toward the chuck 202. In some embodiments, the DUT 203 is drawn toward the chuck 202 using vacuum. In some embodiments, the DUT 203 is held on the chuck 202 by vacuum suction.

In some embodiments, the DUT 203 includes circuitry formed thereon. In some embodiments, several test pads for testing operations are formed over the DUT 203. In some embodiments, the supporting member 102 and the optical fiber 107 are disposed above the DUT 203. In some embodiments, a coupler is disposed over the DUT 203 and configured to receive an optical signal. In some embodiments, the end portion 107a of the optical fiber 107 is aligned with the corresponding coupler over the DUT 203.

In some embodiments, the DUT 203 includes a front side 203a and a back side 203b opposite to the front side 203a. In some embodiments, circuitry or a device is formed over the front side 203a. In some embodiments, the test pads and the couplers are formed over the front side 203a. In some embodiments, the back side 203b of the DUT 203 contacts the chuck 202.

In some embodiments, a stage 108 is disposed within the opening (101a and 102a) and configured to displace and orient the supporting member 102 and the optical fiber 107. In some embodiments, the supporting member 102 is movable along its two axes (X and Y axes). In some embodiments, the supporting member 102 is movable along its three axes (X, Y and Z axes). In some embodiments, the supporting member 102 is rotatable about one or more of its three axes (X, Y and Z axes). In some embodiments, the movement or the rotation of the supporting member 102 can be operated manually or motorized (e.g. by one or more motor).

In some embodiments, the supporting member 102 is displaceable relative to the circuit board 201. In some embodiments, a position and an orientation of the supporting member 102 are adjustable by the stage 108. In some embodiments, the supporting member 102 is movable and rotatable by the stage 108, such that the optical fiber 107 can align with the coupler or other component of the DUT 203. In some embodiments, the dielectric membrane 103 is displaceable relative to the circuit board 201. In some embodiments, a position and an orientation of the dielectric membrane 103 are adjustable by the stage 108. In some embodiments, the dielectric membrane 103 is movable and rotatable by the stage 108, such that the probes 106 can align with the test pad or other components of the DUT 203.

In the present disclosure, a probing method S500 is disclosed. In some embodiments, the DUT 203 is tested by the probing method S500. In some embodiments, the probing method S500 is implemented by the probing system 400. In some embodiments, the probing method S500 involves the first probe card 100. The method S500 includes a number of operations and the description and illustrations are not deemed as a limitation of the sequence of the operations.

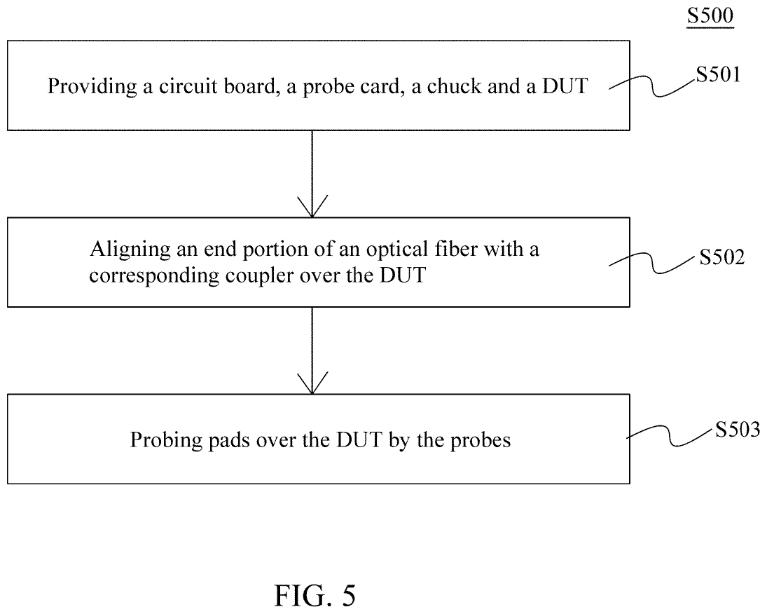

FIG. 5 is a flowchart depicting an embodiment of the probing method S500. The probing method S500 includes steps S501, S502 and S503. In some embodiments, the steps S501, S502 and S503 are implemented by the probing system 400 described above or illustrated in FIG. 4. In some embodiments, the probing system 400 involves the first probe card 100 described above or illustrated in FIG. 1, the second probe card 200 described above or illustrated in FIG. 2 or the third probe card 300 described above or illustrated in FIG. 3.

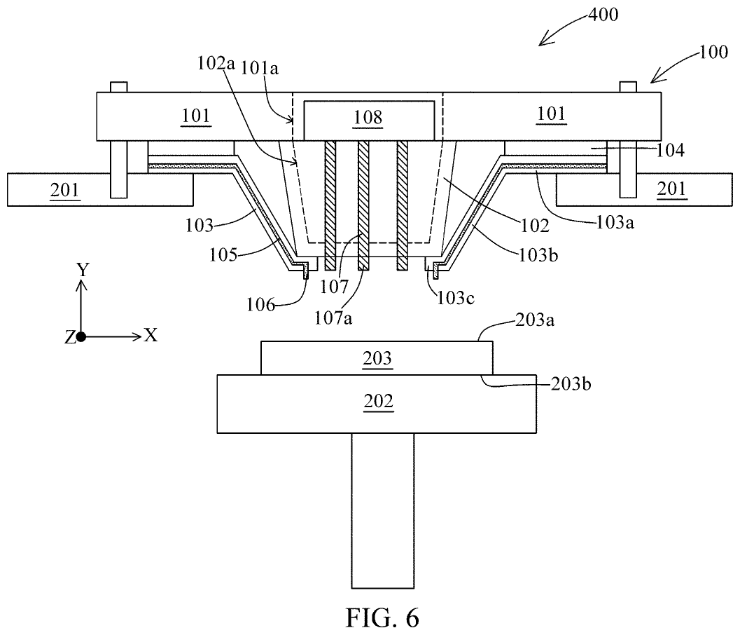

In step S501, a circuit board 201, a first probe card 100, a chuck 202 and a DUT 203 are provided as shown in FIG. 6. In some embodiments, the first probe card 100 is mounted on the circuit board 201, and the DUT 203 is disposed on the chuck 202. In some embodiments, the first probe card 100 is attached to the circuit board 201 by a screw, fastener or any other suitable means.

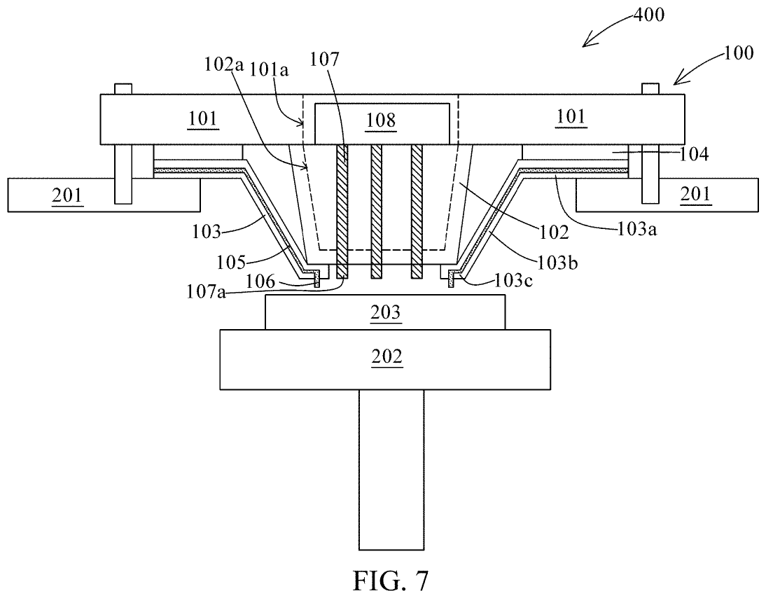

FIGS. 6-8 only illustrate the first probe card 100 is mounted on the circuit board 201, however it is not intended to be limited to such embodiment. A person ordinarily skilled in the art would readily understand that the second probe card 200, the third probe card 300 or any other suitable types of probe cards can also be mounted on the circuit board 201, and all such embodiments are fully intended to be included within the scope of the present disclosure.

In some embodiments, the DUT 203 is disposed on the chuck 202 by sucking the DUT 203 toward the chuck 202. In some embodiments, the DUT 203 is disposed by drawing the DUT 203 toward the chuck 202 using vacuum. In some embodiments, the first probe card 100 is configured as described above or as illustrated in FIG. 1. In some embodiments, the circuit board 201, the chuck 202 and the DUT 203 are configured as the probing system 400 described above or illustrated in FIG. 4.

In step S502, an end portion 107a of the optical fiber 107 is aligned with a coupler over the DUT 203 as shown in FIG. 5. In some embodiments, the chuck 202 moves toward the first probe card 100, and then the supporting member 102 and the dielectric membrane 103 are moved or rotated to align the end portion 107a of the optical fiber 107 and the probes 106 with corresponding components over the DUT 203. In some embodiments, the DUT 203 is moved closer to the supporting member 102, the optical fiber 107 and the probes 106, and then the supporting member 102 and the dielectric membrane 103 are moved or rotated by a stage or the like to align the end portion 107a of the optical fiber 107 and the probes 106 with the corresponding components (e.g., coupler, test pad, or the like) over the DUT 203.

In some embodiments, the end portion 107a of the optical fiber 107 and the probes 106 are aligned with the corresponding components of the DUT 203 by moving or rotating the supporting member 102 and the dielectric membrane 103 relative to the circuit board 201 and the frame 101. In some embodiments, the supporting member 102 and the dielectric membrane 103 are moved or rotated relative to the DUT 203. In some embodiments, all of the optical fibers 107 are aligned with the corresponding couplers on the DUT 203 simultaneously.

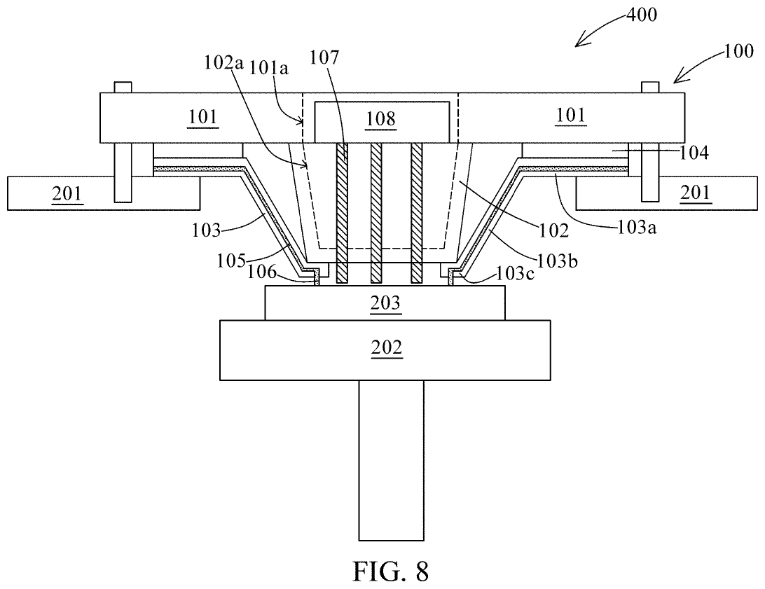

In step S503, several pads over the DUT 203 are probed by the probes 106 as shown in FIG. 8. In some embodiments, the DUT 203 is probed by the probes 106 by moving the supporting member 102 and the dielectric membrane 103 toward the DUT 203, or by moving the chuck 202 and the DUT 203 toward the first probe card 100. In some embodiments, the supporting member 102 and the dielectric membrane 103 are moved toward the DUT 203, so that the probes 106 can contact the corresponding components over the DUT 203. In some embodiments, the test pads on the DUT 203 contact the probes 106 correspondingly, and the couplers on the DUT 203 couple with the end portion 107a of the optical fiber 107 correspondingly. In some embodiments, the end portion 107a of the optical fiber 107 is in contact with or almost in contact with the coupler of the DUT 203.

During the testing, an optical signal (e.g., light beam or the like) is transmitted to the DUT 203 through the optical fiber 107 and the coupler of the DUT 203, and then a response signal from the DUT 203 is transmitted to the probes 106 in response to the optical signal. In some embodiments, the response signal can be an optical/light signal, electrical signal, radio frequency (RF) signal or the like.

After completion of the testing, the chuck 202 is lowered and the DUT 203 is moved away from the first probe card 100, and then the DUT 203 is unloaded from the chuck 202.

Although the present disclosure and its advantages have been described in detail, it should be understood that various changes, substitutions and alterations can be made herein without departing from the spirit and scope of the disclosure as defined by the appended claims. For example, many of the processes discussed above can be implemented through different methods, replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, and steps.

What is claimed is:

1. A probe card (100) comprising:
a frame (101);
a supporting member (102) disposed on and protruding from the frame;
an opening (101a and 102a) extending through the frame and into the supporting member;
an optical fiber (107) disposed along and protruding from the supporting member; and
a plurality of probes (106) protruding from the frame and disposed adjacent to the optical fiber.

2. The probe card of claim 1, wherein the optical fiber is surrounded by the plurality of probes.

3. The probe card of claim 1, wherein the plurality of probes are protruded from a dielectric membrane disposed on the frame and along the supporting member, and the optical fiber is surrounded by the dielectric membrane.

4. The probe card of claim 1, wherein the optical fiber is disposed within the opening or along a surface of the supporting member.

5. The probe card of claim 1, wherein the optical fiber is at least partially attached to the supporting member.

6. The probe card of claim 1, wherein the optical fiber is a fiber array block (FAB) or includes a plurality of optical fibers.

7. The probe card of claim 1, wherein the supporting member is made of glass or ceramic.

8. The probe card of claim 3, wherein the dielectric membrane is at least partially attached to the supporting member.

9. The probe card of claim 1, wherein the supporting member is spaced apart from the plurality of probes.

10. The probe card of claim 3, wherein the dielectric membrane is flexible.

11. The probe card of claim 1, wherein the plurality of probes are electrically connected to a circuit board through a plurality of signal traces.

12. A probing system (200) comprising:
a circuit board (201);
is a probe card (202) including a frame (101) mounted on the circuit board, a supporting member (102) protruding from the frame, an opening (101a and 102a) extending through the frame and the supporting member, an optical fiber (107) disposed along and protruding from the supporting member, and a plurality of probes (106) protruding from the frame and disposed adjacent to the optical fiber; and
a chuck (202) configured to support a device under test (DUT) (203),
wherein the supporting member and the optical fiber are disposed above the chuck.

13. The probing system of claim 12, wherein the supporting member and the optical fiber are surrounded by and protrude from the circuit board.

14. The probing system of claim 12, wherein an end of the optical fiber is aligned with a corresponding coupler over the DUT.

15. The probing system of claim 12, further comprising a stage disposed within the opening and configured to displace and orient the supporting member and the optical fiber.

16. The probing system of claim 12, wherein the supporting member is displaceable relative to the circuit board.

17. A probing method (S500), comprising:
is providing a circuit board (201), a probe card (100) over the circuit board, a chuck (202) under the circuit board and the probe card, and a device under test (DUT) (203) on the chuck, wherein the probe card includes a frame (101) mounted on the circuit board, a supporting member (102) protruding from the frame, an opening (101a and 102a) extending through the frame and the supporting member, an optical fiber (107) disposed along and protruding from the supporting member, and a plurality of probes (106) protruding from the frame and disposed adjacent to the optical fiber (S501);
aligning an end portion (107a) of the optical fiber with a coupler over the DUT (S502); and
probing a plurality of pads over the DUT by the plurality of probes (S503).

18. The probing method of claim 17, wherein the alignment includes moving or rotating the supporting member relative to the DUT.

19. The probing method of claim 17, wherein the DUT is probed by the plurality of probes by moving the supporting member toward the DUT, or moving the chuck and the DUT toward the probe card.

20. The probing method of claim 17, further comprising:
transmitting an optical signal to the DUT through the optical fiber; and
transmitting a response signal from the DUT to the plurality of probes in response to the optical signal.
